(19) United States
(12) Patent Application Publication
(10) Pub. No.: US 2026/0262522 A1
(43) Pub. Date: Sep. 3, 2026

(54) CIRCUIT BOARD, AND SEMICONDUCTOR PACKAGE COMPRISING SAME

(71) Applicant: LG INNOTEK CO., LTD., Seoul (KR)

(72) Inventors: Hae Sik KIM, Seoul (KR); Yu Jin LEE, Seoul (KR)

(73) Assignee: LG INNOTEK CO., LTD., Seoul (KR)

(21) Appl. No.: 19/154,574

(22) PCT Filed: Feb. 8, 2024
(86) PCT No.: PCT/KR2024/001912

§ 371 Date: Aug. 7, 2025

(30) Foreign Application Priority Data
Feb. 9, 2023 (KR) 10-2023-0017557

(51) Int. Cl. H10W 70/652; H10W 70/63

(52) U.S. Cl. CPC H10W 70/652; H10W 70/635

(57) ABSTRACT

A circuit board according to an embodiment includes a core layer; a first wiring electrode disposed on the core layer; a build-up insulating layer disposed on the first wiring electrode; and a second wiring electrode disposed on the build-up insulating layer, wherein the second wiring electrode has a slope whose width decreases in a horizontal direction along a vertical direction from an upper surface of the second wiring electrode toward a lower surface of the second wiring electrode.

### TECHNICAL FIELD

An embodiment relates to a circuit board, and more particularly, to a circuit board including a fine circuit pattern formed by a tenting process and a semiconductor package including the same.

### BACKGROUND ART

A semiconductor package has a structure in which at least one chip is mounted on a circuit board. At this time, high functionalization and high integration of electronic devices are required, and thus high density of the circuit board applied to the semiconductor package is required. In addition, the circuit board applied to the semiconductor package has a multilayer structure.

A product group to which circuit boards with a multilayer structure are applied includes FCBGA (Flip Chip Ball Grid Array) and FCCSP (Flip-Chip Chip Scale Package). A circuit board applied to FCBGA or FCCSP may include a core layer.

The core layer has a thickness of 150 μm or more to implement multilayer buildup.

Furthermore, the core layer includes a through electrode for electrical connection between wiring electrodes located on different layers.

The wiring electrodes disposed on upper and/or lower surfaces of the core layer are formed using a semi-additive process (SAP), a modified semi-additive process (MSAP), or a tenting process.

When the wiring electrodes are formed using SAP and/or MSAP process, the product price increases due to the need for a relatively expensive copper layer. Furthermore, when the wiring electrodes are formed using SAP and/or MSAP process, a process of etching a seed layer must be included as a final step, which complicates the manufacturing process.

Furthermore, when the wiring electrode is formed using the tenting process, a loss of a circuit line width occurs during an etching step of a metal layer, and accordingly, there is a problem in that it is difficult to micronize the winding electrode. This loss of the circuit line width means a large difference in width between upper and lower surfaces of the wiring electrode.

Therefore, when the wiring electrode formed on the upper and/or lower surfaces of the core layer using the tenting process, the wiring electrode only included a pad connected to the through electrode and a dummy electrode. In other words, the wiring electrode formed on the upper and/or lower surfaces of the core layer could not include circuit wiring, such as traces, due to the difficulty in miniaturization.

(Patent Document 1) KR 10-2014-0046225 A

### DISCLOSURE

### Technical Problem

An embodiment provides a circuit board having a novel structure and a semiconductor package including the same.

In addition, the embodiment provides a circuit board including a wiring electrode manufactured using a tenting process and a semiconductor package including the same.

In addition, the embodiment provides a circuit board including a wiring electrode having traces disposed on upper and/or lower surfaces of a core layer and a semiconductor package including the same.

In addition, the embodiment invention provides a circuit board with improved circuit integration and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### TECHNICAL SOLUTION

A circuit board according to an embodiment comprises a core layer; a first wiring electrode disposed on the core layer; a build-up insulating layer disposed on the first wiring electrode; and a second wiring electrode disposed on the build-up insulating layer, wherein the second wiring electrode has a slope whose width decreases in a horizontal direction along a vertical direction from an upper surface of the second wiring electrode toward a lower surface of the second wiring electrode.

In addition, the first wiring electrode has a slope that is different from the slope of the second wiring electrode.

In addition, the slope of the first wiring electrode is inclined in a different direction from the slope of the second wiring electrode.

In addition, the first wiring electrode has a slope that width increases in the horizontal direction along the vertical direction.

In addition, the core layer has a thickness of 150 μm to 600 μm, and wherein the first wiring electrode includes: a pad electrode overlapping the first through electrode and the insulating member in the vertical direction; and a connection electrode connected to the pad electrode and not overlapping the first through electrode and the insulating member in the vertical direction.

In addition, a width of an upper surface of the connection electrode satisfies a range of 90% to 99% of a width of a lower surface of the connection electrode.

In addition, a first interior angle between an upper surface of the connection electrode and a side surface of the connection electrode satisfies a range of 91° to 100°, and wherein a second interior angle between a lower surface of the connection electrode and a side surface of the connection electrode satisfies a range of 80° to 89°.

In addition, the connection electrode includes a plurality of connection electrode patterns spaced apart from each other in the horizontal direction, and wherein a spacing between two adjacent connection electrode patterns among the plurality of connection electrode patterns satisfies a range of 5 μm to 30 μm.

In addition, an interior angle between an upper surface of the second wiring electrode and a side surface of the second wiring electrode is an acute angle, and wherein an interior angle between a lower surface of the second wiring electrode and a side surface of the second wiring electrode is an obtuse angle.

In addition, the core layer includes a through hole, and wherein a width of the through hole in the horizontal direction satisfies a range of 80 μm to 500 μm.

In addition, the circuit board further includes an insulating member disposed in the through hole; and a first through electrode surrounding at least a portion of the insulating member.

Meanwhile, a circuit board according to an embodiment comprises a first insulating layer having a through hole; an insulating member disposed in the through hole; a first through electrode disposed in the through hole and surrounding at least a portion of the insulating member; and a first wiring electrode disposed on the first insulating layer, wherein the first insulating layer is a core layer having a thickness of 150 μm to 600 μm, and the first wiring electrode includes a pad electrode overlapping the first through electrode and the insulating member in a vertical direction; and a connection electrode connected to the pad electrode and not overlapping the first through electrode and the insulating member in the vertical direction.

In addition, a width of an upper surface of the connection electrode is smaller than a width of a lower surface of the connection electrode.

In addition, a width of a lower surface of the connection electrode satisfies a range of 5 μm to 30 μm.

In addition, a width of an upper surface of the connection electrode satisfies a range of 90% to 99% of a width of the lower surface of the connection electrode.

In addition, a first interior angle between the upper surface of the connection electrode and the side surface of the connection electrode ranges from 91° to 100°, and a second interior angle between the lower surface of the connection electrode and the side surface of the connection electrode ranges from 80° to 89°.

In addition, the connection electrode includes a plurality of connection electrode patterns spaced apart from each other in a horizontal direction, and a spacing between two adjacent connection electrode patterns among the plurality of connection electrode patterns satisfies a range of 5 μm to 30 μm.

In addition, the connection electrode has a thickness of 15 μm to 30 μm.

In addition, an etching factor of the connection electrode satisfies a range of 10 to 60, and the etching factor is calculated as “thickness of the connection electrode/((width of the lower surface of the connection electrode-width of the upper surface of the connection electrode)/2)”.

In addition, the circuit board includes a second insulating layer disposed on the first insulating layer; and a second wiring electrode disposed on the second insulating layer, wherein a slope of a side surface of the second wiring electrode is inclined in a different direction than a slope of a side surface of the connection electrode.

In addition, a width of an upper surface of the second wiring electrode is greater than a width of a lower surface of the second wiring electrode.

In addition, an interior angle between an upper surface of the second wiring electrode and a side surface of the second wiring electrode is an acute angle, and an interior angle between a lower surface of the second wiring electrode and a side surface of the second wiring electrode is an obtuse angle.

In addition, a width of the through hole in a horizontal direction satisfies a range of 80 μm to 500 μm.

Meanwhile, a semiconductor package according to an embodiment includes a first insulating layer having a through hole; an insulating member disposed in the through hole; a first through electrode disposed in the through hole and surrounding at least a portion of the insulating member; a first wiring electrode disposed on the first insulating layer; at least one second insulating layer disposed on the first insulating layer; a second wiring electrode disposed on at least one second insulating layer; a conductive bonding part disposed on the second wiring electrode; a connecting part disposed on the conductive bonding part; and a semiconductor device disposed on the connecting part, wherein the first insulating layer is a core layer having a thickness of 150 μm to 600 μm, the first wiring electrode includes a pad electrode overlapping the first through electrode and the insulating member in a vertical direction; and a connection electrode connected to the pad electrode and not overlapping the first through electrode and the insulating member in the vertical direction, wherein a width of an upper surface of the connection electrode is smaller than a width of a lower surface of the connection electrode, a width of a lower surface of the connection electrode satisfies a range of 5 μm to 30 μm, a width of an upper surface of the connection electrode satisfies a range of 90% to 99% of a width of a lower surface of the connection electrode, and the connection electrode includes a plurality of connection electrode patterns spaced apart from each other in a horizontal direction, and a spacing between two adjacent connection electrode patterns among the plurality of connection electrode patterns satisfies a range of 5 μm to 30 μm.

In addition, a slope of a side surface of the second wiring electrode is inclined in a different direction from a slope of a side surface of the connection electrode, a width of the upper surface of the second wiring electrode is greater than a width of the lower surface of the second wiring electrode, an interior angle between the upper surface of the second wiring electrode and the side surface of the second wiring electrode is an acute angle, and the interior angle between the lower surface of the second wiring electrode and the side surface of the second wiring electrode is an obtuse angle.

In addition, the semiconductor device includes a plurality of semiconductor devices spaced apart in a horizontal direction, and the semiconductor package further includes a connection member embedded in the first insulating layer and horizontally electrically connecting the plurality of semiconductor devices.

### Advantageous Effects

An embodiment includes a first insulating layer having a through hole, an insulating member disposed in the through hole, a first through electrode disposed in the through hole and surrounding at least a portion of the insulating member, and a first wiring electrode disposed on the first insulating layer. The first insulating layer is a core layer having a thickness of 150 μm to 600 μm, and the first wiring electrode includes a pad electrode overlapping the first through electrode and the insulating member in a vertical direction; and a connection electrode connected to the pad electrode and not overlapping the first through electrode and the insulating member in the vertical direction.

Furthermore, a width of an upper surface of the connection electrode is smaller than a width of a lower surface of the connection electrode, the width of the lower surface of the connection electrode satisfies a range of 5 μm to 30 μm, and the width of the upper surface of the connection electrode satisfies a range of 90% to 99% of the width of the lower surface of the connection electrode.

That is, the first wiring electrode of the embodiment is manufactured using a tenting process and includes a connection electrode in addition to the pad electrode.

That is, since the first wiring electrode is manufactured using a tenting process, the embodiment can simplify a process compared to wiring electrodes manufactured using MSAP and/or SAP processes, thereby dramatically reducing an unit cost of the circuit board.

Furthermore, since the first wiring electrode is manufactured using a tenting process and includes a connection electrode, the embodiment can improve the circuit integration of the circuit board, thereby miniaturizing the circuit board and semiconductor package.

Specifically, in a comparative example compared to the embodiment, when the first wiring electrode is manufactured using a tenting process, a difference between a width of the upper and a width of the lower surface of the electrode pattern occurs during the etching process of the first wiring electrode. Consequently, a width of the electrode pattern and a spacing between adjacent electrode patterns increase due to this difference.

For example, in a case of the electrode pattern manufactured using the tenting process of the comparative example, a width of the electrode pattern exceeds at least 35 μm, and a spacing between adjacent electrode patterns exceeds at least 35 μm. This is because the difference between the width of the upper and the width of the lower surface of the electrode patterns must be taken into account.

In contrast, the embodiment manufactures the first wiring electrode using an etching agent with an anisotropic etching structure. This minimizes the difference between a width of the upper and a width of the lower surface of the connection electrode of the first wiring electrode. Consequently, the embodiment can improve circuit integration by including a connection electrode, such as a trace, in the first wiring electrode, thereby enabling miniaturization of the circuit board and semiconductor package.

Furthermore, the embodiment can enhance the freedom of circuit board wiring design by including the connection electrode in the first wiring electrode, thereby enhancing user satisfaction.

Furthermore, the embodiment can easily control the wiring density of the first wiring electrode 121 by including the connection electrode in the first wiring electrode. Through this, the embodiment can adjust a wiring density of the first wiring electrode by considering a warpage direction of the circuit board, thereby resolving reliability issues the reliability problem of the circuit board and the semiconductor package warping significantly in a specific direction.

Furthermore, the embodiment can utilize the connection electrode of the first wiring electrode as a heat transfer path that functions as a heat dissipation path, thereby improving the heat dissipation characteristics of the circuit board and semiconductor package.

Accordingly, the embodiment can allow a semiconductor device attached to a circuit board to operate stably, thereby allowing electronic products such as servers to which the semiconductor package is applied to operate stably. Through this, the embodiment can improve product satisfaction and product reliability.

### DESCRIPTION OF DRAWINGS

FIG. 1 is a cross-sectional view illustrating a circuit board according to an embodiment.

FIG. 2 is an enlarged view of an inner layer region of FIG. 1.

FIG. 3 is a plan view illustrating an inner layer region of FIG. 2.

FIG. 4 is an enlarged view illustrating a connection pattern of a first wiring electrode of FIG. 2.

FIG. 5 is a cross-sectional view illustrating the connection pattern of the first wiring electrode compared to the embodiment.

FIG. 6 is an enlarged view illustrating a connection pattern of a second wiring electrode of FIG. 1.

FIG. 7 is a cross-sectional view illustrating a semiconductor package according to a first embodiment.

FIG. 8 is a cross-sectional view illustrating a semiconductor package according to a second embodiment.

FIGS. 9 to 19 are cross-sectional views illustrating a manufacturing method of the circuit board illustrated in FIG. 1 in order of processes.

### BEST MODE

Hereinafter, embodiments will be described in detail with reference to the accompanying drawings.

However, the spirit and scope of the present invention is not limited to a part of the embodiments described, and may be implemented in various other forms, and within the spirit and scope of the present invention, one or more of the elements of the embodiments may be selectively combined and redisposed.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art. Further, the terms used in the embodiments of the present invention are for describing the embodiments and are not intended to limit the present invention.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present invention, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “connected” to another element, it may include not only when the element is directly “connected” to, “coupled” to, or “connected” to other elements, but also when the element is “connected”, “coupled”, or “connected” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements. Furthermore, when expressed as “on (over)” or “under (below)”, it may include not only the upper direction but also the lower direction based on one element.

### Electronic Device

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

### Circuit board

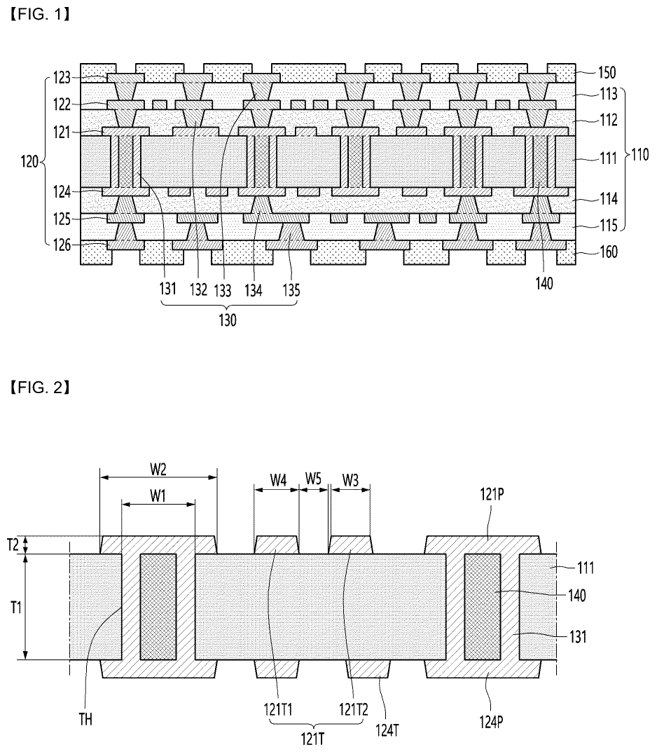

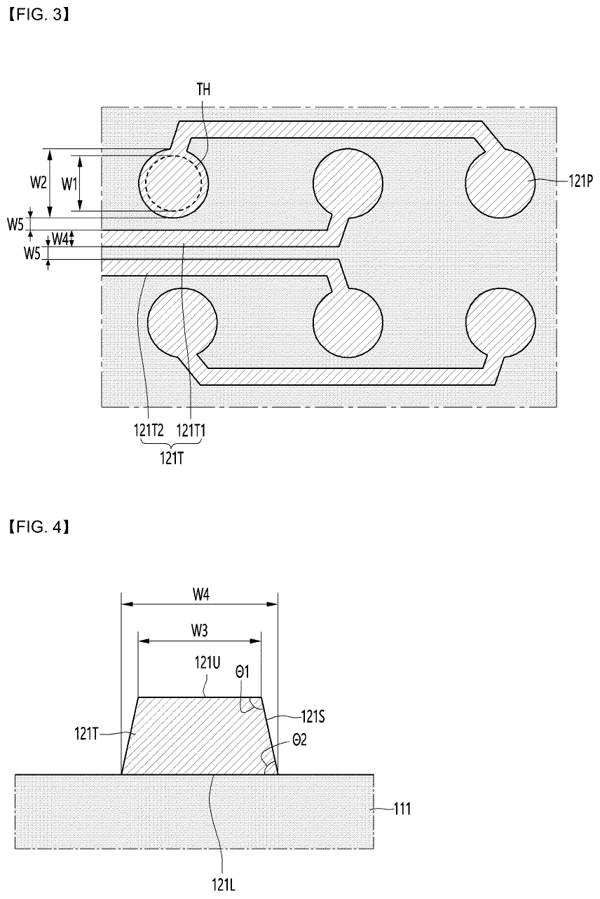

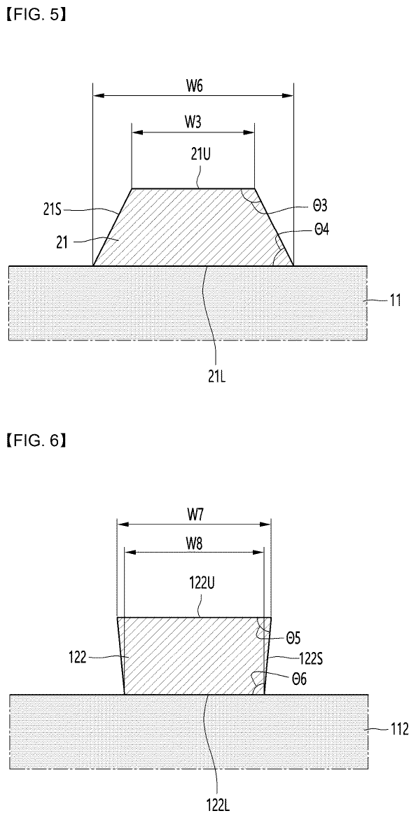

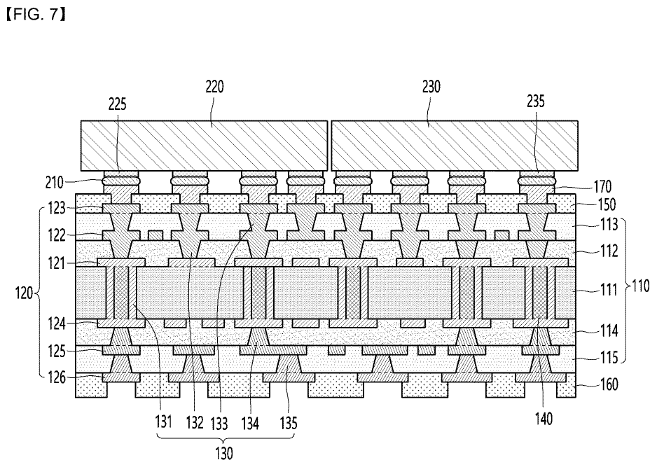

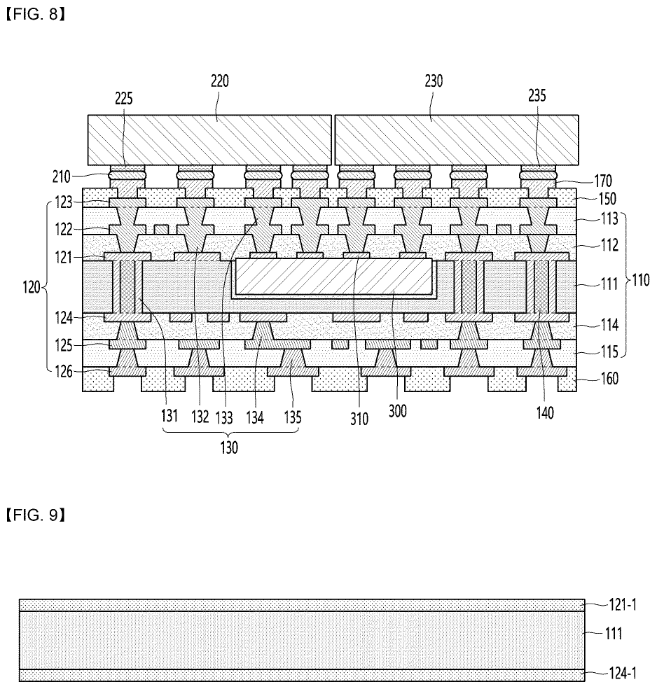

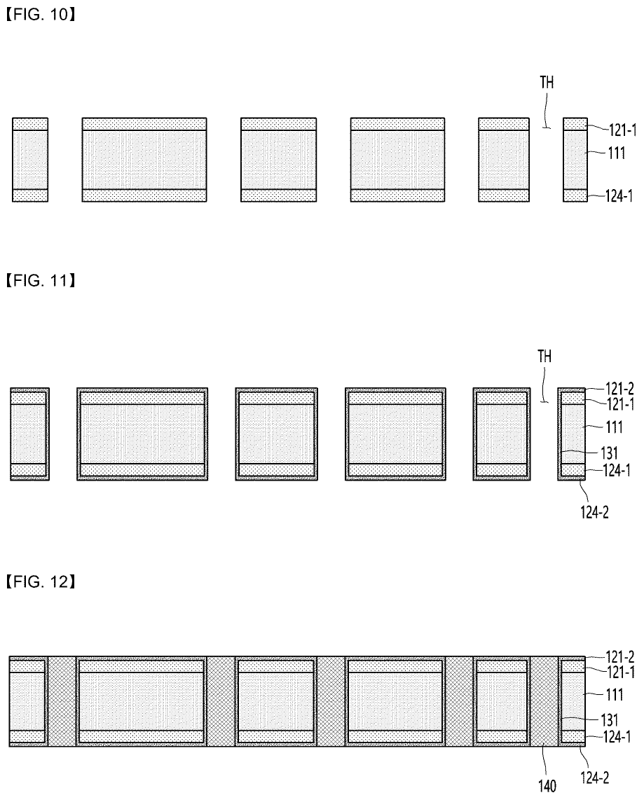

FIG. 1 is a cross-sectional view illustrating a circuit board according to an embodiment, FIG. 2 is an enlarged view of an inner layer region of FIG. 1, FIG. 3 is a plan view illustrating an inner layer region of FIG. 2, FIG. 4 is an enlarged view illustrating a connection pattern of a first wiring electrode of FIG. 2, FIG. 5 is a cross-sectional view illustrating the connection pattern of the first wiring electrode compared to the embodiment, and FIG. 6 is an enlarged view illustrating a connection pattern of a second wiring electrode of FIG. 1.

Hereinafter, a circuit board according to an embodiment will be described in detail with reference to FIGS. 1 to 6.

Referring to FIG. 1, the circuit board allows at least one semiconductor device to be attached. Furthermore, the circuit board can be coupled to an external substrate. For example, the external substrate may be a main board of an electronic device, for example, a motherboard. Furthermore, the external substrate may be a separate memory package including a memory device, or an interposer connecting the memory package and the circuit board of the embodiment.

The circuit board includes an insulating layer 110. The insulating layer 110 may be formed of multiple layers.

In one embodiment, as illustrated in FIG. 1, the insulating layer 110 may have a five-layer structure, but the embodiment is not limited thereto. For example, in other embodiments, the insulating layer 110 may have a layer structure of four or fewer layers, or six or more layers.

The circuit board of the embodiment may be a core board, and thus, at least one of the multiple layers of the insulating layer 110 may be provided as a core layer.

For example, the insulating layer 110 may include a first insulating layer 111. The first insulating layer 111 may be a core layer. The first insulating layer 111 may be a rigid insulating member. Preferably, the first insulating layer 111 may be a copper clad laminate (CCL).

In particular, a CCL is a substrate from which circuit boards are typically manufactured, and is a laminate in which copper foil is laminated on an insulating layer. Depending on the intended use, the CCL may include a glass/epoxy CCL, a heat-resistant resin CCL, a paper/phenol CCL, a high-frequency CCL, a flexible CCL (e.g., polyimide film), and a composite CCL. Here, the first insulating layer 111 of the embodiment may be a glass/epoxy copper-clad laminate for the production of double-sided circuit boards and multilayer circuit boards, but is not limited thereto.

The glass/epoxy copper-clad laminate comprises a reinforcing substrate made by impregnating glass fibers or organic fibers with epoxy resin, and copper foil. The glass/epoxy copper-clad laminate is classified according to the reinforcing substrate. For example, glass/epoxy copper-clad laminates are classified by grade, such as FR-1 to FR-5, according to the standards set by the National Electrical Manufacturers Association (NEMA) based on the reinforcing substrate and heat resistance. Generally, among the FR-1 to FR-5 grades, FR-4 is the most commonly used, but demand for FR-5, which has improved glass transition temperature (Tg) characteristics, is also increasing recently.

The first insulating layer 111 may have a certain thickness (T1, see FIG. 2). At this time, a thickness T1 of the first insulating layer 111 may exceed 150 μm, or exceed 200 μm, or exceed 300 μm, or exceed 400 μm.

For example, the thickness T1 of the first insulating layer 111 may satisfy a range of 150 μm to 600 μm. For example, the thickness T1 of the first insulating layer 111 may satisfy a range of 200 μm to 580 μm. For example, the thickness T1 of the first insulating layer 111 may satisfy a range of 250 μm to 550 μm.

If the thickness T1 of the first insulating layer 111 is less than 150 μm, the rigidity and warpage characteristics of the circuit board may deteriorate. In addition, if the thickness of the first insulating layer 111 exceeds 600 μm, the thickness of the circuit board increases, making it difficult to miniaturize the semiconductor package.

Build-up insulating layers may be disposed on and below the first insulating layer 111. In this case, an upper build-up insulating layer disposed on the first insulating layer 111 and a lower build-up insulating layer disposed under the first insulating layer 111 may have a symmetrical structure with respect to the first insulating layer 111, but this is not limited thereto.

In one embodiment, the number of layers of the upper build-up insulating layer disposed on the first insulating layer 111 may be the same as the number of layers of the lower build-up insulating layer disposed under the first insulating layer 111.

In another embodiment, the number of layers of the upper build-up insulating layer disposed on the first insulating layer 111 and the number of layers of the lower build-up insulating layer disposed under the first insulating layer 111 may be different.

A second insulating layer 112 and a third insulating layer 113 may be disposed on the first insulating layer 111. In addition, a fourth insulating layer 114 and a fifth insulating layer 115 may be disposed under the first insulating layer 111.

The second insulating layer 112, the third insulating layer 113, the fourth insulating layer 114, and the fifth insulating layer 115 may include an insulating material different from that of the first insulating layer 111. For example, the second insulating layer 112, the third insulating layer 113, the fourth insulating layer 114, and the fifth insulating layer 115 may not include a reinforcing member, such as glass fiber, that is present in the first insulating layer 111.

For example, the second insulating layer 112, the third insulating layer 113, the fourth insulating layer 114, and the fifth insulating layer 115 may be formed of a material including an inorganic filler and an insulating resin. For example, the second insulating layer 112, the third insulating layer 113, the fourth insulating layer 114, and the fifth insulating layer 115 may include a structure in which an inorganic filler such as silica or alumina is dispersed within a thermosetting resin such as an epoxy resin or a thermoplastic resin such as a polyimide. For example, the second insulating layer 112, the third insulating layer 113, the fourth insulating layer 114, and the fifth insulating layer 115 may include ABF (Ajinomoto Build-up Film), BT (Bismaleimide Triazine), and PID (Photo Imageable Dielectric resin).

The circuit board includes an electrode part. The electrode section includes a wiring electrode 120 and a through electrode 130.

The wiring electrode 120 may refer to an electrode pattern, such as a pad and/or trace, disposed on the upper and/or lower surfaces of each of the first insulating layer 111, the second insulating layer 112, the third insulating layer 113, the fourth insulating layer 114, and the fifth insulating layer 115. Furthermore, the through electrode 130 may refer to a via electrode penetrating at least one of the first insulating layer 111, the second insulating layer 112, the third insulating layer 113, the fourth insulating layer 114, and the fifth insulating layer 115.

The wiring electrode 120 may include a first wiring electrode 121, a second wiring electrode 122, a third wiring electrode 123, a fourth wiring electrode 124, a fifth wiring electrode 125, and a sixth wiring electrode 126.

The first wiring electrode 121 may be disposed on an upper surface of the first insulating layer 111. The second wiring electrode 122 may be disposed on an upper surface of the second insulating layer 122. The third wiring electrode 123 may be disposed on an upper surface of the third insulating layer 113. The fourth wiring electrode 124 may be disposed on a lower surface of the first insulating layer 111. The fifth wiring electrode 125 may be disposed on a lower surface of the fourth insulating layer 114. The sixth wiring electrode 126 may be disposed on a lower surface of the fifth insulating layer 115.

At least one of the first wiring electrode 121, the second wiring electrode 122, the third wiring electrode 123, the fourth wiring electrode 124, the fifth wiring electrode 125, and the sixth wiring electrode 126 may be manufactured using a different method from at least one of the others.

For example, the first wiring electrode 121 and the fourth wiring electrode 124 disposed on the surface of the first insulating layer 111 may be manufactured using a different manufacturing method from a manufacturing method of the second wiring electrode 122, the third wiring electrode 123, the fifth wiring electrode 125, and the sixth wiring electrode 126.

Specifically, the first wiring electrode 121 and the fourth wiring electrode 124 may be manufactured using a tenting process. For example, the first wiring electrode 121 and the fourth wiring electrode 124 may be formed by forming a metal layer on a copper foil layer and then removing the copper foil layer and the metal layer by etching.

The second wiring electrode 122, the third wiring electrode 123, the fifth wiring electrode 125, and the sixth wiring electrode 126 can be manufactured using a Modified Semi Additive Process (MSAP) and/or a Semi Additive Process (SAP). For example, the second wiring electrode 122, the third wiring electrode 123, the fifth wiring electrode 125, and the sixth wiring electrode 126 can be formed by forming a circuit pattern corresponding to the wiring electrode on a seed layer and then removing the seed layer by etching. At this time, the seed layer can optionally include a copper foil layer depending on a manufacturing method.

At this time, the first wiring electrode 121 and the fourth wiring electrode 124 of the embodiment each include a pad electrode 121P, and 124P connected to the through electrode 130. In addition, each of the first wiring electrode 121 and the fourth wiring electrode 124 of the embodiment includes a connection electrode 121T, and 124T connected to the pad electrode 121P, and 124P. That is, the embodiment provides the first wiring electrode 121 and the fourth wiring electrode 124 with the connection electrode 121T, and 124T as well as the pad electrode 121P, and 124P while manufacturing them using a tenting process. At this time, the pad electrode 121P, and 124P may be an electrode that overlaps the first through electrode 131 and the insulating member 140 in a vertical direction, and the connection electrode 121T, and 124T may be an electrode that does not overlap the first through electrode 131 and the insulating member 140 in a vertical direction.

That is, in the embodiment, since the first wiring electrode 121 and the fourth wiring electrode 124 are manufactured using the tenting process, the process can be simplified compared to wiring electrodes manufactured using the MSAP and/or SAP methods, thereby drastically reducing the unit cost of the circuit board.

Furthermore, in the embodiment, since the first wiring electrode 121 and the fourth wiring electrode 124 are manufactured using the tenting process and include connection electrodes 121T, and 124T, the circuit integration of the circuit board can be improved, thereby miniaturizing the circuit board and semiconductor package.

Specifically, in a comparative example compared to the embodiment, when the first wiring electrode and the fourth wiring electrode are manufactured using the tenting process, a difference in the upper and lower surface widths of the electrode patterns occurs during the etching process of each of the first and fourth wiring electrodes. Consequently, the width of the electrode patterns and the spacing between adjacent electrode patterns increase due to this difference.

For example, in a case of electrode patterns manufactured using the tenting process of the comparative example, the width of the electrode patterns exceeds at least 35 μm, and the spacing between adjacent electrode patterns exceeds at least 35 μm. This is because the difference between upper and lower widths of the electrode patterns must be taken into account.

In contrast, the embodiment manufactures the first wiring electrode 121 and the fourth wiring electrode 124 using an etching agent having an anisotropic etching structure. Through this, the embodiment can minimize the difference between upper and lower widths of the connection electrodes 121T, and 124T of the first wiring electrode 121 and the fourth wiring electrode 124, respectively. Accordingly, the width of the connection electrodes 121T, and 124T of the embodiment may be 30 μm or less, 25 μm or less, 20 μm or less, 15 μm or less, or 10 μm or less, and a spacing between adjacent connection electrodes may be 30 μm or less, 25 μm or less, 20 μm or less, 15 μm or less, or 10 μm or less.

Thus, the embodiment can improve circuit integration by having the first wiring electrode 121 and the fourth wiring electrode 124 as connection electrodes 121T, and 124T that are trace-like, thereby enabling miniaturization of the circuit board and semiconductor package.

Furthermore, the embodiment can improve the degree of freedom in circuit board wiring design by having the first wiring electrode 121T, and 124T and the fourth wiring electrode 124 as connection electrodes 121T, and 124T, thereby enhancing user satisfaction.

In addition, since the embodiment includes connection electrodes 121T, and 124T for the first wiring electrode 121 and the fourth wiring electrode 124, the wiring density of each of the first wiring electrode 121 and the fourth wiring electrode 124 can be easily adjusted (e.g., a planar area of the first wiring electrode 121 and a planar area of the fourth wiring electrode 124). Accordingly, the embodiment can adjust the wiring densities of the first wiring electrode 121 and the fourth wiring electrode 124 by considering a warpage direction of the circuit board, thereby resolving reliability issues in which the circuit board and semiconductor package are significantly bent in a specific direction.

Furthermore, the embodiment can utilize the connection electrodes 121T, and 124T of the first wiring electrode 121 and the fourth wiring electrode 124 as heat transfer paths that function as heat dissipation, thereby improving the heat dissipation characteristics of the circuit board and semiconductor package.

Through this, the embodiment can ensure that a semiconductor device attached to a circuit board operates stably, and thus, electronic products such as servers to which semiconductor packages are applied can operate stably. Through this, the embodiment can improve product satisfaction and product reliability.

Each of the first wiring electrode 121 and the fourth wiring electrode 124 may have a thickness (T2, see FIG. 2) in a range of 15 μm to 30 μm. For example, each of the first wiring electrode 121 and the fourth wiring electrode 124 may have a thickness T2 in a range of 17 μm to 28 μm. For example, each of the first wiring electrode 121 and the fourth wiring electrode 124 may have a thickness T2 in a range of 18 μm to 25 μm.

If the thickness T2 of each of the first wiring electrode 121 and the fourth wiring electrode 124 is less than 15 μm, it may be difficult to manufacture the first wiring electrode 121 and the fourth wiring electrode 124 using the tenting process. If the thickness T2 of each of the first wiring electrode 121 and the fourth wiring electrode 124 is less than 15 μm, it may be difficult to form an electrode pattern with a uniform thickness on the surface of the first insulating layer 111 corresponding to the core layer, and thus the electrical characteristics of the circuit board and the semiconductor package may deteriorate. If the thickness T2 of each of the first wiring electrode 121 and the fourth wiring electrode 124 exceeds 30 μm, it may be difficult for the first wiring electrode 121 and the fourth wiring electrode 124 to be provided with connection electrodes 121T, and 124T.

Meanwhile, the thicknesses of the second wiring electrode 122, the third wiring electrode 123, the fifth wiring electrode 125, and the sixth wiring electrode 126 may correspond to the respective thicknesses T2 of the first wiring electrode 121 and the fourth wiring electrode 124, but are not limited thereto. For example, the thicknesses of the second wiring electrode 122, the third wiring electrode 123, the fifth wiring electrode 125, and the sixth wiring electrode 126 may be smaller than the respective thicknesses T2 of the first wiring electrode 121 and the fourth wiring electrode 124.

Furthermore, the through electrode 130 may be provided to penetrate each insulating layer.

For example, the first through electrode 131 may penetrate the first insulating layer 111. The first through electrode 131 can electrically connect the first wiring electrode 121 and the fourth wiring electrode 124.

The second through electrode 132 can penetrate the second insulating layer 112. The second through electrode 132 can electrically connect the first wiring electrode 121 and the second wiring electrode 122.

The third through electrode 133 can penetrate the third insulating layer 113. The third through electrode 133 can electrically connect the second wiring electrode 122 and the third wiring electrode 123.

The fourth through electrode 134 can penetrate the fourth insulating layer 114. The fourth through electrode 134 can electrically connect the fourth wiring electrode 124 and the fifth wiring electrode 125.

The fifth through electrode 135 can penetrate the fifth insulating layer 115. The fifth through electrode 135 can electrically connect the fifth wiring electrode 125 and the third wiring electrode 126.

At this time, a slope of a side surface of the first through electrode 131 may be different from slopes of side surfaces of the second to fifth through electrodes 132, 133, 134, and 135. For example, the slope of the side surface of the first through electrode 131 may be perpendicular to the upper or lower surface of the first insulating layer 111. For example, the width of the first through electrode 131 may not change from the upper surface to the lower surface.

In contrast, the slope of each side surface of the second to fifth through electrodes 132, 133, 134, and 135 may be inclined at a predetermined slope with respect to the upper or lower surface of the first wiring electrode 121. For example, the width of each of the second to fifth through electrodes 132, 133, 134, and 135 may vary from the upper surface to the lower surface.

However, the embodiment is not limited thereto. For example, the first through electrode 131 may be formed using a laser method, and in this case, the side surfaces of the first through electrode 131 may include a plurality of protruding surfaces spaced apart from each other in the vertical direction and protruding in the horizontal direction.

In addition, the wiring electrode 120 and the through electrode 130 may be formed of at least one metal selected from gold (Au), silver (Ag), platinum (Pt), titanium (Ti), tin (Sn), copper (Cu), and zinc (Zn). Furthermore, the wiring electrode 120 and the through electrode 130 may be formed of a paste or solder paste containing at least one metal selected from gold (Au), silver (Ag), platinum (Pt), titanium (Ti), tin (Sn), copper (Cu), and zinc (Zn) with excellent bonding strength. Preferably, the wiring electrode 120 and the through electrode 130 may be formed of copper (Cu), which is relatively inexpensive.

In this embodiment, the first wiring electrode 121 and the fourth wiring electrode 124 are manufactured using a tenting process. Accordingly, it may be difficult to form a through electrode that completely fills the through hole TH of the first insulating layer 111 using a plating method. Therefore, the first through electrode 131 may be formed by partially filling the through hole TH of the first insulating layer 111.

Furthermore, an insulating member 140 may be formed within a through hole TH of the first insulating layer 111. The insulating member 140 may be formed within the through hole TH of the first insulating layer 111, and thus, the first through electrode 131 may be formed to surround a side portion of the insulating member 140 filled within the through hole TH.

The insulating member 140 may include an insulating material. For example, the insulating member 140 may include an insulating ink material. For example, the insulating member 140 may also be referred to as a hole plugging member.

Furthermore, the circuit board includes a protective layer.

The first protective layer 150 is disposed on the third insulating layer 113. The first protective layer 150 can protect the upper surface of the third insulating layer 113. In addition, the first protective layer 150 can protect the upper surface of the third wiring electrode 123. The first protective layer 150 can include at least one opening overlapping with a pad connected to a terminal of a semiconductor device among the third wiring electrodes 123 in a vertical direction.

The second protective layer 160 is disposed under the fifth insulating layer 115. The second protective layer 160 can protect the lower surface of the fifth insulating layer 115. In addition, the second protective layer 160 can protect the lower surface of the sixth wiring electrode 126. The second protective layer 160 may include at least one opening overlapping with a pad connected to an electrode of an external substrate (e.g., a main board) among the sixth wiring electrodes 126 in a vertical direction.

The first protective layer 150 and the second protective layer 160 may include an insulating material. The first protective layer 150 and the second protective layer 160 may include various materials that can be applied and then cured by heating to protect the surfaces of the insulating layer and the circuit layer.

The first protective layer 150 and the second protective layer 160 may be solder resist layers containing an organic polymer material. For example, the first protective layer 150 and the second protective layer 160 may include an epoxy acrylate-based resin. Specifically, the first protective layer 150 and the second protective layer 160 may include a resin, a curing agent, a photoinitiator, a pigment, a solvent, a filler, an additive, an acrylic-based monomer, and the like. However, the embodiment is not limited thereto, and the first protective layer 150 and the second protective layer 160 may be any one of a photo solder resist layer, a cover-lay, and a polymer material.

Below, the specific structure of the first wiring electrode 121 according to the embodiment will be described. Furthermore, the first wiring electrode 121 of the embodiment and the wiring electrode formed using the tenting process of the comparative example will be described below. Furthermore, a difference in shapes of the first wiring electrode 121 and the second wiring electrode 122 will be described below.

Referring to FIGS. 2 to 4, the first wiring electrode 121 is positioned on the upper surface of the first insulating layer 111, and the fourth wiring electrode 124 is positioned on the lower surface of the first insulating layer 111.

The first wiring electrode 121 includes a pad electrode 121P that overlaps the first through electrode 131 in a vertical direction. Furthermore, the first wiring electrode 121 includes a connection electrode 121T that electrically connects the plurality of pad electrodes 121P of the first wiring electrode 121. The connection electrode 121T of the first wiring electrode 121 may refer to a trace connected to the pad electrode 121P.

Furthermore, the fourth wiring electrode 124 includes a pad electrode 124P overlapping the first through electrode 131 in a vertical direction and a connection electrode 124T connected to the pad electrode 124P of the fourth wiring electrode 124. At this time, the fourth wiring electrode 124 may have a structure substantially corresponding to the first wiring electrode 121, and a following description will be based on the first wiring electrode 121.

At this time, the thickness T1 of the first insulating layer 111 may satisfy the range of 150 μm to 600 μm, or 200 μm to 580 μm, or 250 μm to 550 μm, as described above.

In addition, the thickness T2 of the first wiring electrode 120 can satisfy a range of 15 μm to 30 μm, or 17 μm to 28 μm, or 18 μm to 25 μm.

Here, a through hole TH is provided in the first insulating layer 111. A width W1 of the through hole TH in the horizontal direction can satisfy a range of 80 μm to 500 μm. For example, the width W1 of the through hole TH of the first insulating layer 111 in the horizontal direction can satisfy a range of 90 μm to 480 μm. In addition, the width W1 of the through hole TH of the first insulating layer 111 in the horizontal direction can satisfy a range of 95 μm to 450 μm.

If the width W1 of the through hole TH of the first insulating layer 111 is less than 80 μm, a reliability problem may occur in which the through hole TH does not penetrate the first insulating layer 111 having a predetermined thickness T1. If the width W1 of the through hole TH of the first insulating layer 111 exceeds 500 μm, an area of the circuit board may increase, making miniaturization of the circuit board and semiconductor package difficult, or it may be difficult to provide a connection electrode 121T to the first wiring electrode 120.

A width W2 of the pad electrode 121P of the first wiring electrode 121 may be determined based on the width W1 of the through hole TH. For example, the width W2 of the pad electrode 121P of the first wiring electrode 121 may range from 1.1 to 2 times the width W1 of the through hole TH. For example, the width W2 of the pad electrode 121P of the first wiring electrode 121 may range from 1.2 to 1.8 times the width W1 of the through hole TH. For example, the width W2 of the pad electrode 121P of the first wiring electrode 121 may range from 1.2 to 1.6 times the width W1 of the through hole TH.

If the width W2 of the pad electrode 121P of the first wiring electrode 121 is less than 1.1 times the width W1 of the through hole TH, a reliability problem may occur in which the pad electrode 121P is not electrically connected to the first through electrode 131 provided in the through hole TH. If the width W2 of the pad electrode 121P of the first wiring electrode 121 exceeds twice the width W1 of the through hole TH, the area of the circuit board increases, making it difficult to miniaturize the circuit board and semiconductor package, or it may be difficult to provide a connection electrode 121T to the first wiring electrode 120.

At this time, the pad electrode 121P of the first wiring electrode 121 may have different widths on the upper surface and the lower surface. Preferably, the width of the upper surface of the pad electrode 121P of the first wiring electrode 121 may be smaller than the width of the lower surface of the pad electrode 121P. This may occur because the pad electrode 121P of the first wiring electrode 121 is manufactured using a tenting process.

Here, the pad electrode 121P of the first wiring electrode 121 has a relatively large width W2 compared to the connection electrode 121T. Accordingly, the difference between the width of the upper surface of the pad electrode 121P and the width of the lower surface of the pad electrode 121P may not significantly affect the circuit density of the first wiring electrode 121. However, the circuit density of the first wiring electrode 121 is affected by the difference between the width of the upper surface of the connection electrode 121T of the first wiring electrode 121 and the width of the lower surface of the connection electrode 121T. Furthermore, the difference between the width of the upper surface of the pad electrode 121P of the first wiring electrode 121 and the width of the lower surface of the pad electrode 121P may correspond to the difference between the width of the upper surface of the connection electrode 121T of the first wiring electrode 121 and the width of the lower surface of the connection electrode 121T. Accordingly, the difference between the width of the upper surface of the pad electrode 121P of the first wiring electrode 121 and the width of the lower surface of the pad electrode 121P may correspond to the difference between the width W3 of the upper surface of the connection electrode 121T and the width W4 of the lower surface of the connection electrode 121T, which will be described below.

The first wiring electrode 121 includes a connection electrode 121T.

At this time, the connection electrode 121T may include first and second connection electrode patterns 121T1, and 121T2 that are spaced apart from each other on the first insulating layer 111 in a horizontal direction.

The first and second connection electrode patterns 121T1, and 121T2 may each have different widths W3 of the upper surface and W4 of the lower surface. Preferably, the width W3 of the upper surface of each of the first and second connection electrode patterns 121T1, and 121T2 may be smaller than the width W4 of the lower surface. This may be a structural characteristic resulting from the manufacturing of the first and second connection electrode patterns 121T1, and 121T2 using a tenting process.

However, the embodiment forms the first and second connection electrode patterns 121T1, and 121T2 using an etching agent having an anisotropic etching structure. Here, the anisotropic etching structure may also be referred to as a vertical etching structure. For example, the anisotropic etching structure may refer to a structure in which etching is selectively performed only in the vertical direction without horizontal expansion during the etching process.

For example, the embodiment forms the first wiring electrode 121 by etching a metal layer using an etching agent containing copper chloride and/or iron chloride. Through this, the embodiment can minimize the difference between the width of the upper surface and the width of the lower surface of each of the pad electrode 121P and the connection electrode 121T of the first wiring electrode 121. Accordingly, the embodiment can minimize the width of each of the pad electrodes 121P and the connection electrodes 121T and the spacing between adjacent electrodes.

To briefly explain the etching process of the metal layer by the etching agent of the embodiment, the etching agent may include an organic material that functions as a barrier. Accordingly, when etching the metal layer, the organic material may adhere to a surface of the metal layer. At this time, the adhered organic material may be removed when in direct contact with the etching agent. Therefore, when etching the metal layer, a region that vertically overlaps the open region of the dry film may directly contact the etching agent, thereby removing the organic material that functions as a barrier and thereby performing etching in the vertical direction. In contrast, a region that does not vertically overlap the open region of the dry film may not directly contact the etching agent, and thus the organic material that functions as a barrier may not be removed, and thus etching in the horizontal direction that does not overlap the open region may not occur. Therefore, the embodiment enables the formation of a wiring electrode whose upper surface width and lower surface width are substantially the same.

The width W4 of the lower surfaces of each of the first and second connection electrode patterns 121T1, and 121T2 can satisfy a range of 5 μm to 30 μm. For example, the width W4 of the lower surfaces of each of the first and second connection electrode patterns 121T1, and 121T2 can satisfy a range of 5 μm to 25 μm. For example, the width W4 of the lower surfaces of each of the first and second connection electrode patterns 121T1, and 121T2 can satisfy a range of 5 μm to 20 μm.

At this time, if the width W4 of the lower surfaces of each of the first and second connection electrode patterns 121T1, and 121T2 is less than 5 μm, the width of the upper surfaces of each of the first and second connection electrode patterns 121T1, and 121T2 may become excessively narrow due to manufacturing errors. Accordingly, vertical cross-sectional shapes of the first and second connection electrode patterns 121T1, and 121T2 may be close to triangles, which may prevent the first and second connection electrode patterns 121T1, and 121T2 from functioning as traces. If the width W4 of the lower surfaces of each of the first and second connection electrode patterns 121T1, and 121T2 exceeds 30 μm, it may be difficult to arrange the connection electrode 121T of the first wiring electrode 121 within a limited space, which may result in a reduction in circuit integration.

The width W3 of the upper surfaces of each of the first and second connection electrode patterns 121T1, and 121T2 may correspond to the width W4 of the lower surfaces. Here, “corresponding” may mean that the width W3 of the upper surface is smaller than the width W4 of the lower surface, and the difference between them is 2 μm or less, 1.5 μm or less, or 1 μm or less.

For example, the width W3 of the upper surface of each of the first and second connection electrode patterns 121T1, and 121T2 may satisfy a range of 90% to 99% of the width W4 of the lower surface. For example, the width W3 of the upper surface of each of the first and second connection electrode patterns 121T1, and 121T2 may satisfy a range of 92% to 99% of the width W4 of the lower surface. For example, the width W3 of the upper surface of each of the first and second connection electrode patterns 121T1, and 121T2 may satisfy a range of 95% to 99% of the width W4 of the lower surface.

If the width W3 of the upper surface of each of the first and second connection electrode patterns 121T1, and 121T2 is less than 90% of the width W4 of the lower surface, the width of each of the first and second connection electrode patterns 121T1, and 121T2 or the spacing therebetween may increase, and accordingly, it may be difficult for the first wiring electrode 121 to have the connection electrode 121T. If the width W3 of the upper surface of each of the first and second connection electrode patterns 121T1, and 121T2 exceeds 99% of the width W4 of the lower surface, this means that the etching in the vertical direction by the etching agent of the embodiment is not smoothly performed, and accordingly, the electrical characteristics of the first wiring electrode 121 may be deteriorated. For example, it may be impossible to form the first and second connection electrode patterns 121T1, and 121T2 so that the width W3 of the upper surface thereof exceeds 99% of the width W4 of the lower surface thereof using a tenting process.

Through this, the embodiment can provide the first wiring electrode 121 and the fourth wiring electrode 124 disposed on the upper and lower surfaces of the first insulating layer 111, respectively, with pad electrodes 121P, and 124P and connection electrodes 121T, and 124T.

Furthermore, the embodiment can minimize the spacing W5 between a plurality of adjacent connection electrode patterns by forming the connection electrode 121T of the first wiring electrode 121 using an etching agent having an anisotropic etching structure.

For example, the spacing W5 between adjacent first and second connection electrode patterns 121T1, and 121T2 can satisfy a range of 5 μm to 30 μm. For example, the spacing W5 between adjacent first and second connection electrode patterns 121T1, and 121T2 can satisfy a range of 5 μm to 25 μm. For example, the spacing W5 between adjacent first and second connection electrode patterns 121T1, and 121T2 can satisfy a range of 5 μm to 20 μm.

At this time, if the spacing W5 between adjacent first and second connection electrode patterns 121T1, and 121T2 is less than 5 μm, the first and second connection electrode patterns 121T1, and 121T2 may come into contact with each other due to manufacturing errors, which can lead to electrical reliability issues such as electrical shorts. In addition, if the spacing W5 between the adjacent first and second connection electrode patterns 121T1, and 121T2 exceeds 30 μm, it may be difficult to place the connection electrode 121T of the first wiring electrode 121 within the limited space, which may result in a decrease in circuit integration.

Furthermore, a side surface 121S of the connection electrode 121T of the first wiring electrode 121 may have a slope that increases in width from the upper surface 121U of the connection electrode 121T toward the lower surface 121L. In this case, a slope of the side surface 121S of the connection electrode 121T may be close to 90 degrees.

The slope of the side surface 121S of the connection electrode 121T of the first wiring electrode 121 may mean a first interior angle θ between the upper surface 121U and the side surface 121S, and may mean a second interior angle θ between the lower surface 121L and the side surface 121S.

The first interior angle θ may satisfy a range of 91° to 100°. Preferably, the first interior angle θ may satisfy a range of 91° to 98°. More preferably, the first interior angle θ may satisfy a range of 91° to 95°. Correspondingly, the second interior angle θ may satisfy a range of 80° to 89°. Preferably, the second interior angle θ may satisfy a range of 82° to 89°. More preferably, the second interior angle θ may satisfy a range of 85° to It can satisfy the range of 89°. At this time, when the side surface 121S of the connection electrode 121T has a curve, the first interior angle θ and the second interior angle θ may each mean an interior angle between an imaginary straight line connecting an innermost point and an outermost point on the side surface 121S and the upper surface 121U or lower surface 121L of the connection electrode 121T.

If the first interior angle θ is less than 91° or the second interior angle e exceeds 89°, it means that the etching in the vertical direction by the etching agent of the embodiment is not smoothly performed, and thus the electrical characteristics of the first wiring electrode 121 may be deteriorated. For example, it may be difficult to form a connection electrode 121T having a first interior angle θ of less than 91° or a second interior angle θ exceeding 89° by a tenting process. In addition, if the first interior angle θ exceeds 100°or the second interior angle θ is less than 80°, the widths of each of the first and second connection electrode patterns 121T1, and 121T2 or the spacing therebetween may increase, and thus it may be difficult for the first wiring electrode 121 to have the connection electrode 121T.

At this time, when manufacturing the first wiring electrode 121, The metal layer used may have a following etching factor. Preferably, the etching factor of the first wiring electrode 121 may be as follows.

Here, the etching factor may be defined by the following Equation 1.

$$Etching factor = Thickness of connection electrode / \\ ( Width of lower surface of connection electrode - Width of upper surface of connection electrode ) / 2 ) \qquad [ Equation 1 ]$$

The etching factor of the first wiring electrode 121 of the embodiment may be 10 to 60. Preferably, the etching factor of the first wiring electrode 121 of the embodiment may be 12 to 58. More preferably, the etching factor of the first wiring electrode 121 of the embodiment may be 15 to 55.

In addition, when the etching factor of the first wiring electrode 121 of the embodiment is outside the range of 10 to 60, the width of the upper surface, the width of the lower surface of the connection electrode 121T, the difference in width between the width of the upper surface and the width of the lower surface, the spacing between the plurality of connection electrode patterns, and the slope of the side surface of the connection electrode may not satisfy the above-described range.

Meanwhile, referring to FIG. 5, when the width W3 of the upper surface of the connection electrode 21 of the comparative example manufactured by the tenting process compared to the embodiment is the same as the width W3 of the upper surface of the connection electrode 121T of the present invention, the width W5 of the lower surface of the connection electrode 21 of the comparative example exceeds 110% of the width W3 of the upper surface of the connection electrode 21. This is because the connection electrode 21 of the comparative example is manufactured using an etching agent having an isotropic etching structure, not an etching agent having an anisotropic etching structure like the embodiment, and thus, the metal layer is etched while expanding in the horizontal direction.

Furthermore, the interior angle θ between the upper surface 21U and the side surface 21S of the connection electrode 21 of the comparative example is 110°. and further, the interior angle θ between the side surface 21S of the lower surface 21L of the connection electrode 21 is less than 75°.

Therefore, in the comparative example, it is difficult to place the connection electrode on the upper surface and/or lower surface of the core layer, and thus only a dummy pattern is disposed in a corresponding region. In contrast, in the embodiment, it is possible to place the first wiring electrode 121 and the fourth wiring electrode 124, which include the connection electrode, on the upper surface and lower surface of the first insulating layer 111, which is the core layer, respectively.

Meanwhile, referring to FIG. 6, the second wiring electrode 122 is disposed on the second insulating layer 112. At this time, a vertical cross-sectional shape of the second wiring electrode 122 may be different from a vertical cross-sectional shape of the first wiring electrode 121.

For example, the second wiring electrode 122 is manufactured using the MSAP method or the SAP method, unlike the first wiring electrode 121. Therefore, the manufacturing of the second wiring electrode 122 includes a process of finally etching the seed layer from the metal layer including the seed layer.

Therefore, a width W7 of the upper surface 122U of the second wiring electrode 122 may be greater than a width W8 of the lower surface 122L of the second wiring electrode 122. For example, a side surface 122S of the second wiring electrode 122 may have a slope in which the width decreases from the upper surface 122U of the second wiring electrode 122 toward the lower surface 122L of the second wiring electrode 122.

That is, the slope of the side surface 122S of the second wiring electrode 122 may be inclined in a different direction from the slope of the side surface 121S of the first wiring electrode 121.

Therefore, the interior angle θ between the side surface 122S and the upper surface 122U of the second wiring electrode 122 may have an acute angle, unlike the first interior angle θ of the first wiring electrode 121. In addition, the interior angle e between the side surface 122S and the lower surface 122L of the second wiring electrode 122 may have an obtuse angle, unlike the second interior angle θ of the first wiring electrode 121.

An embodiment includes a first insulating layer having a through hole, an insulating member disposed in the through hole, a first through electrode disposed in the through hole and surrounding at least a portion of the insulating member, and a first wiring electrode disposed on the first insulating layer. The first insulating layer is a core layer having a thickness of 150 μm to 600 μm, and the first wiring electrode includes a pad electrode overlapping the first through electrode and the insulating member in a vertical direction; and a connection electrode connected to the pad electrode and not overlapping the first through electrode and the insulating member in the vertical direction.

Furthermore, a width of an upper surface of the connection electrode is smaller than a width of a lower surface of the connection electrode, the width of the lower surface of the connection electrode satisfies a range of 5 μm to 30 μm, and the width of the upper surface of the connection electrode satisfies a range of 90% to 99% of the width of the lower surface of the connection electrode.

That is, the first wiring electrode of the embodiment is manufactured using a tenting process and includes a connection electrode in addition to the pad electrode.

That is, since the first wiring electrode is manufactured using a tenting process, the embodiment can simplify a process compared to wiring electrodes manufactured using MSAP and/or SAP processes, thereby dramatically reducing an unit cost of the circuit board.

Furthermore, since the first wiring electrode is manufactured using a tenting process and includes a connection electrode, the embodiment can improve the circuit integration of the circuit board, thereby miniaturizing the circuit board and semiconductor package.

Specifically, in a comparative example compared to the embodiment, when the first wiring electrode is manufactured using a tenting process, a difference between a width of the upper and a width of the lower surface of the electrode pattern occurs during the etching process of the first wiring electrode. Consequently, a width of the electrode pattern and a spacing between adjacent electrode patterns increase due to this difference.

For example, in a case of the electrode pattern manufactured using the tenting process of the comparative example, a width of the electrode pattern exceeds at least 35 μm, and a spacing between adjacent electrode patterns exceeds at least 35 μm. This is because the difference between the width of the upper and the width of the lower surface of the electrode patterns must be taken into account.

In contrast, the embodiment manufactures the first wiring electrode using an etching agent with an anisotropic etching structure. This minimizes the difference between a width of the upper and a width of the lower surface of the connection electrode of the first wiring electrode. Consequently, the embodiment can improve circuit integration by including a connection electrode, such as a trace, in the first wiring electrode, thereby enabling miniaturization of the circuit board and semiconductor package.

Furthermore, the embodiment can enhance the freedom of circuit board wiring design by including the connection electrode in the first wiring electrode, thereby enhancing user satisfaction.

Furthermore, the embodiment can easily control the wiring density of the first wiring electrode 121 by including the connection electrode in the first wiring electrode. Through this, the embodiment can adjust a wiring density of the first wiring electrode by considering a warpage direction of the circuit board, thereby resolving reliability issues the reliability problem of the circuit board and the semiconductor package warping significantly in a specific direction.

Furthermore, the embodiment can utilize the connection electrode of the first wiring electrode as a heat transfer path that functions as a heat dissipation path, thereby improving the heat dissipation characteristics of the circuit board and semiconductor package.

Accordingly, the embodiment can allow a semiconductor device attached to a circuit board to operate stably, thereby allowing electronic products such as servers to which the semiconductor package is applied to operate stably. Through this, the embodiment can improve product satisfaction and product reliability.

### Semiconductor Package

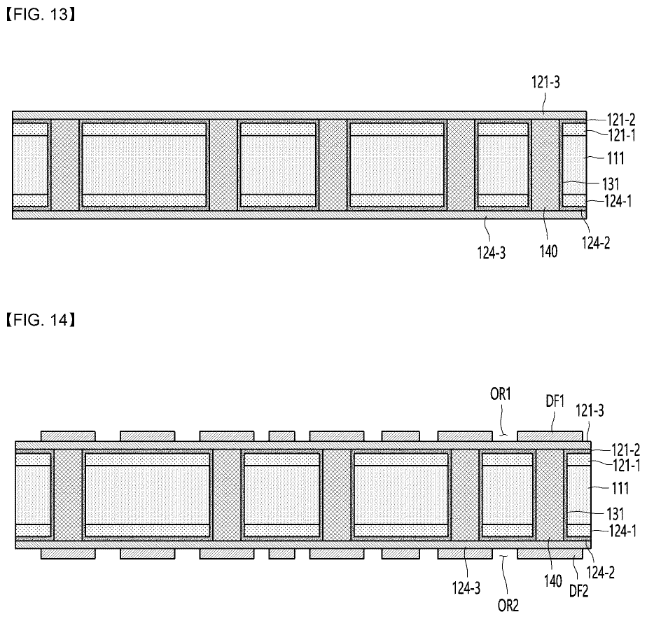

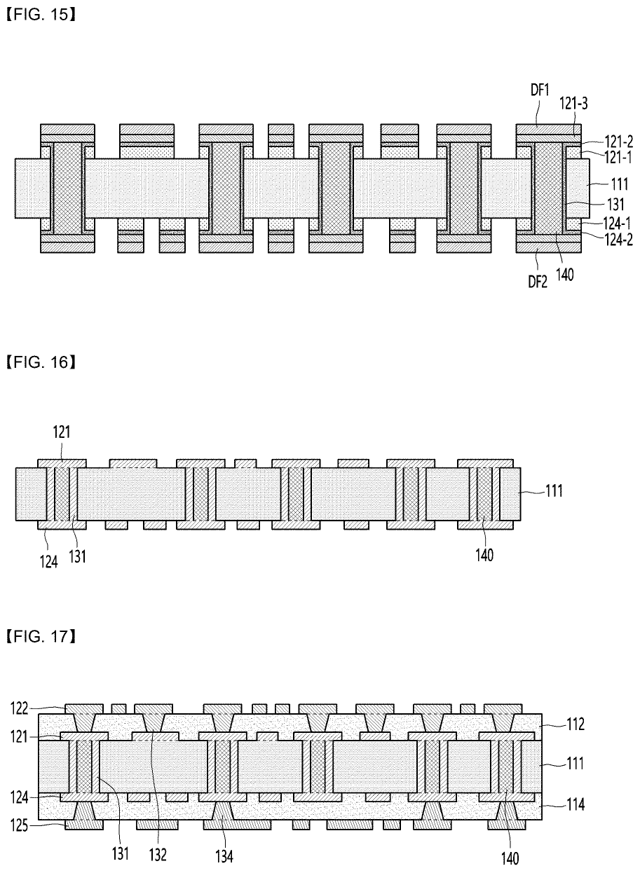

FIG. 7 is a cross-sectional view illustrating a semiconductor package according to a first embodiment, and FIG. 8 is a cross-sectional view illustrating a semiconductor package according to a second embodiment.

Referring to FIG. 7, the semiconductor package may include the circuit board of FIG. 1.

Furthermore, the circuit board may further include a conductive bonding part 170.

The conductive bonding part 170 is positioned on an uppermost wiring electrode among the wiring electrodes positioned on each layer of the insulating layer 110. For example, the conductive bonding part 170 may be positioned on the third wiring electrode 123. The conductive bonding part 170 protrudes above the first protective layer 150. The conductive bonding part 170 may be referred to as a bump.

The conductive bonding part 170 protrudes above the first protective layer 150 of the circuit board to stably connect with the terminals 225, and 235 of the semiconductor device 220, and 230 using the connecting part 210. This allows the conductive bonding part 170 to maintain a certain spacing between the connecting part 210 and the circuit board, thereby improving positional alignment between the conductive bonding part 170 and the terminals of the semiconductor device 220, and 230.

A plurality of conductive bonding parts 170 are provided. The conductive bonding parts 170 are provided in a horizontal direction on the third wiring electrode 123.

The connecting part 210 is disposed on the conductive bonding part 170.

The connecting part 210 can be connected to the terminal 225 of the first semiconductor device 220 and the terminal 235 of the second semiconductor device 230, respectively.

The first semiconductor device 220 and the second semiconductor device 230 are connected to the connecting part 210. In this case, FIG. 7 illustrates the first semiconductor device 220 and the second semiconductor device 230 being connected horizontally and spaced apart from each other on the connecting part 210, but the embodiment is not limited thereto. For example, one semiconductor device may be connected to the connecting part 210, or three or more semiconductor devices may be connected to the connecting part 210.

Meanwhile, although not illustrated in the drawing, the connecting part may also be located under a lowest wiring electrode of the circuit board. Furthermore, an external substrate may be connected to the connecting part located under the lowest wiring electrode. For example, the external substrate may be a main board of an electronic device.

Meanwhile, referring to FIG. 8, the semiconductor package may further include a connection member 300 positioned within the circuit board. The connection member 300 may be embedded within the insulating layer 110 of the circuit board.

The connection member 300 partially overlaps the semiconductor devices 320, and 330 in the vertical direction.

The connection member 300 electrically connects a portion of the terminal 325 of the first semiconductor device 320 to a portion of the terminal 335 of the second semiconductor device 330.

For example, functionally separate semiconductor devices, such as chiplet units, or multiple semiconductor devices with different functions, such as a CPU and GPU, or a GPU and HBM, may be mounted on the circuit board, and the connection member 300 may function to horizontally electrically connect them.

In one embodiment, the connection member 300 is an inorganic bridge. For example, the inorganic bridge may be a silicon bridge. For example, the connection member 300 may include a silicon substrate and a redistribution layer.

In another embodiment, the connection member 300 is an organic bridge. For example, the connection member 300 may include an organic material. For example, the connection member 300 may include an organic substrate in which the silicon substrate of the inorganic bridge is redisposed with an organic material.

The connection member 300 includes a pad part 310. The pad part 310 of the connection member 300 is electrically connected to an electrode part (e.g., a through electrode and a wiring electrode) of the circuit board.

### Circuit Board Manufacturing Method

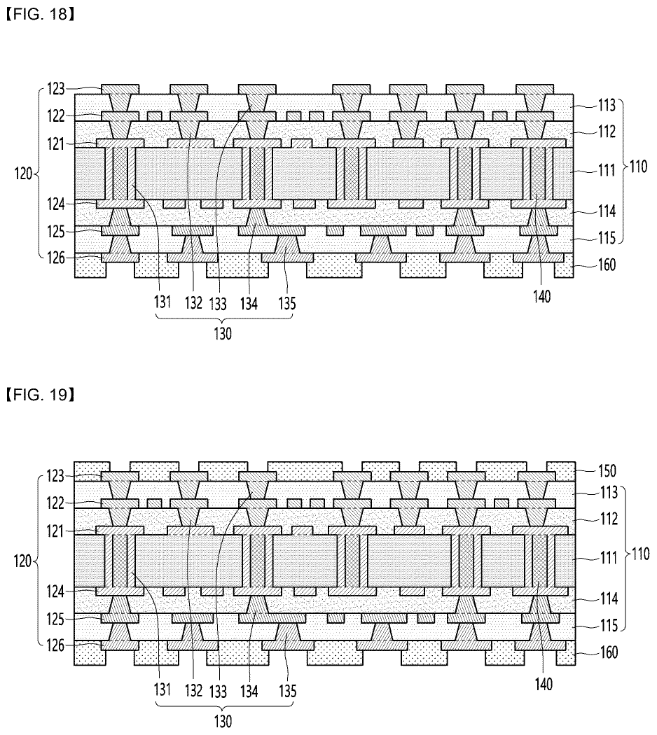

FIGS. 9 to 19 are cross-sectional views illustrating a manufacturing method of the circuit board illustrated in FIG. 1 in order of processes.

First, referring to FIG. 9, the embodiment prepares a member that serves as the basis for manufacturing the circuit board. For example, the embodiment prepares a copper clad laminate (CCL) that serves as the basis for manufacturing a core board. The copper-clad laminate includes a first insulating layer 111. Furthermore, the copper-clad laminate includes copper foil layers disposed on the upper and lower surfaces of the first insulating layer 111, respectively.

For example, the member includes a first insulating layer 111, a first copper foil layer 121-1 disposed on the first insulating layer 111, and a second copper foil layer 124-1 disposed under the first insulating layer 111. At this time, the first copper foil layer 121-1 may constitute a portion of a plurality of metal layers of the first wiring electrode 121. Furthermore, the second copper foil layer 124-1 may constitute a portion of a plurality of metal layers of the fourth wiring electrode 124.

Next, referring to FIG. 10, the embodiment performs a process of forming a through hole TH penetrating the first copper foil layer 121-1, the first insulating layer 111, and the second copper foil layer 124-1. At this time, the process of forming the through hole TH may use a CNC drill, or alternatively, may be formed through a laser process.

Next, referring to FIG. 11, the embodiment may perform a process of forming a metal layer on the upper surface of the first copper foil layer 121-1, the lower surface of the second copper foil layer 124-1, and an inner wall of the through hole TH. That is, the embodiment may form a first metal layer 121-2 constituting the first wiring electrode 121 on the upper surface of the first copper foil layer 121-1. In addition, the embodiment may form a second metal layer 124-2 constituting the fourth wiring electrode 124 on the lower surface of the second copper layer 124-1. Furthermore, the embodiment may form a third metal layer 131 constituting the first through electrode 131 on the inner wall of the through hole TH. In this case, the first to third metal layers 121-2, 124-2, and 131 may essentially be a single metal layer, and may be differentiated based on their placement.

Also, while the embodiment describes forming the first to third metal layers 121-2, 124-2, and 131 through a single plating process, this is not limited thereto. For example, the first to third metal layers 121-2, 124-2, and 131 may be formed through multiple plating processes to achieve a consistent thickness.

Next, referring to FIG. 12, the embodiment may perform a hole plugging process. For example, the embodiment may perform a process of forming an insulating member 140 within a through hole TH of the first insulating layer 111.

Next, referring to FIG. 13, the embodiment may perform a process of forming a fourth metal layer 121-3 on the first metal layer 121-2 and the insulating member 140 of the first wiring electrode 121. The fourth metal layer 121-3 constitutes a portion of the multiple metal layers of the first wiring electrode 121.

Furthermore, the embodiment may perform a process of forming a fifth metal layer 124-3 under the second metal layer 124-2 and the insulating member 140 of the fourth wiring electrode 124. The fifth metal layer 124-3 constitutes a portion of the plurality of metal layers of the fourth wiring electrode 124.

Next, referring to FIG. 14, the embodiment may perform a process of forming a first dry film DF1 on the fourth metal layer 121-3 of the first wiring electrode 121. At this time, the first dry film DF1 may have a first open region OR1. The first open region OR1 may vertically overlap with a region of the upper surface of the fourth metal layer 121-3 where the first wiring electrode 121 is not formed.

Furthermore, the embodiment may perform a process of forming a second dry film DF2 under the fifth metal layer 124-3 of the fourth wiring electrode 124. At this time, the second dry film DF2 may have a second open region OR2. The second open region OR2 may vertically overlap with a region of the lower surface of the fifth metal layer 124-3 where the fourth wiring electrode 124 is not formed.

Next, referring to FIG. 15, the embodiment may perform a process of removing the metal layer exposed through the open region of each of the first dry film DF1 and the second dry film DF2 by etching using an etching agent having an anisotropic etching structure. Through this, the embodiment may form the pad electrode 121P and the connection electrode 121T of the first wiring electrode 121. In addition, the embodiment may form the pad electrode 124P and the connection electrode 124T of the fourth wiring electrode 124.

Next, referring to FIG. 16, the embodiment may perform a process of removing the first dry film DF1 and the second dry film DF2.

Next, referring to FIG. 17, the embodiment may perform a process of laminating a second insulating layer 112 on the first insulating layer 111. Furthermore, the embodiment may perform a process of forming a second through electrode 132 penetrating the second insulating layer 112 and a second wiring electrode 122 positioned on the second insulating layer 112.

Furthermore, the embodiment may perform a process of laminating a fourth insulating layer 114 under the first insulating layer 111. Furthermore, the embodiment may perform a process of forming a fourth through electrode 134 penetrating the fourth insulating layer 114 and a fifth wiring electrode 125 positioned under the fourth insulating layer 114.

Next, referring to FIG. 18, the embodiment may perform a process of laminating a third insulating layer 113 over the second insulating layer 112. In addition, the embodiment may perform a process of forming a third through electrode 133 penetrating the third insulating layer 113 and a third wiring electrode 123 positioned on the third insulating layer 113.

In addition, the embodiment may perform a process of laminating a fifth insulating layer 115 under the fourth insulating layer 114. In addition, the embodiment may perform a process of forming a fifth through electrode 135 penetrating the fifth insulating layer 115 and a sixth wiring electrode 126 positioned under the fifth insulating layer 115.

Next, referring to FIG. 19, the embodiment may perform a process of forming a first protective layer 150 on the third insulating layer 113. In addition, the embodiment may perform a process of forming a second protective layer 160 under the fifth insulating layer 115.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
a core layer;
a first wiring electrode disposed on the core layer;
a build-up insulating layer disposed on the first wiring electrode; and
a second wiring electrode disposed on the build-up insulating layer,
wherein the first wiring electrode has a slope whose width increases in a horizontal direction from an upper surface of the first wiring electrode toward a lower surface of the first wiring electrode,
wherein the second wiring electrode has a slope whose width decreases in a horizontal direction from an upper surface of the second wiring electrode toward a lower surface of the second wiring electrode, and
wherein the first wiring electrode and the second wiring electrode overlap along a vertical direction perpendicular to the horizontal direction.

2. The circuit board of claim 1, further comprising:
a via electrode penetrating at least a portion of the build-up insulating layer along the vertical direction.

3. The circuit board of claim 2, wherein a direction in which a side surface of the via electrode is inclined is same as a direction in which the slope of the second wiring electrode is inclined.

4. The circuit board of claim 2, wherein a side surface of the via electrode is inclined in an opposite direction to a direction in which the slope of the first wiring electrode is inclined.

5. The circuit board of claim 1, wherein the core layer has a thickness of 150 μm to 600 μm, and
wherein the first wiring electrode includes:
a pad electrode overlapping the first through electrode in the vertical direction; and
a connection electrode connected to the pad electrode and not overlapping the first through electrode in the vertical direction.

6. The circuit board of claim 5, wherein a width of an upper surface of the connection electrode satisfies a range of 90% to 99% of a width of a lower surface of the connection electrode.

7. The circuit board of claim 5, wherein a first interior angle between an upper surface of the connection electrode and a side surface of the connection electrode satisfies a range of 91° to 100°, and
wherein a second interior angle between a lower surface of the connection electrode and a side surface of the connection electrode satisfies a range of 80° to 89°.

8. The circuit board of claim 5, wherein the connection electrode includes a plurality of connection electrode patterns spaced apart from each other in the horizontal direction, and
wherein a spacing between two adjacent connection electrode patterns among the plurality of connection electrode patterns satisfies a range of 5 μm to 30 μm.

9. The circuit board of claim 1, wherein an interior angle between an upper surface of the second wiring electrode and a side surface of the second wiring electrode is an acute angle, and
wherein an interior angle between a lower surface of the second wiring electrode and a side surface of the second wiring electrode is an obtuse angle.

10. The circuit board of claim 1, wherein the core layer includes a through hole, and
wherein a width of the through hole in the horizontal direction satisfies a range of 80 μm to 500 μm.

11. The circuit board of claim 10, further comprising:
a through via disposed in the through hole,
wherein a side surface of the through via has a slope different from the slope of the first wiring electrode.

12. The circuit board of claim 11, wherein a side surface of the through via has a slope different from the slope of the second wiring electrode.

13. A semiconductor package substrate comprising:
a core layer;
a first wiring electrode disposed on the core layer;
a build-up insulating layer disposed on the first wiring electrode;
a second wiring electrode disposed on the build-up insulating layer; and
a semiconductor device disposed on the second wiring electrode,
wherein the first wiring electrode and the second wiring electrode have slopes inclined in opposite directions and overlap each other in a vertical direction.

14. The semiconductor package substrate of claim 13, further comprising:
a connection member disposed in the core layer,
wherein the core layer includes a cavity in which the connection member is disposed and is concave from an upper surface of the core layer toward a lower surface of the core layer.

15. The semiconductor package substrate of claim 14, wherein the first wiring electrode has a slope whose width increases in a horizontal direction from an upper surface of the first wiring electrode toward a lower surface of the first wiring electrode, and
wherein the second wiring electrode has a slope whose width decreases in a horizontal direction from an upper surface of the second wiring electrode toward a lower surface of the second wiring electrode.

16. The semiconductor package substrate of claim 14, further comprising:
a via electrode penetrating at least a portion of the build-up insulating layer along the vertical direction, and
wherein a direction in which a side surface of the via electrode is inclined is same as a direction in which the slope of the second wiring electrode is inclined.

17. The semiconductor package substrate of claim 16, wherein a side surface of the via electrode is inclined in an opposite direction to a direction in which the slope of the first wiring electrode is inclined.

18. The semiconductor package substrate of claim 16, wherein the core layer has a thickness of 150 μm to 600 μm,
wherein the first wiring electrode includes:
a pad electrode overlapping the first through electrode in the vertical direction; and
a connection electrode connected to the pad electrode and not overlapping the first through electrode in the vertical direction, and
wherein a width of an upper surface of the connection electrode satisfies a range of 90% to 99% of a width of a lower surface of the connection electrode.

19. The semiconductor package substrate of claim 18, wherein a first interior angle between an upper surface of the connection electrode and a side surface of the connection electrode satisfies a range of 91° to 100°,
wherein a second interior angle between a lower surface of the connection electrode and a side surface of the connection electrode satisfies a range of 80° to 89°,
wherein the connection electrode includes a plurality of connection electrode patterns spaced apart from each other in the horizontal direction, and
wherein a spacing between two adjacent connection electrode patterns among the plurality of connection electrode patterns satisfies a range of 5 μm to 30 μm.

20. The semiconductor package substrate of claim 13, further comprising:
a through via disposed in a through hole penetrating the core layer,
wherein a side surface of the through via has a slope different from the slope of the first wiring electrode.
